(19) United States
(12) Patent Application Publication
(10) Pub. No.: US 2026/0150752 A1
(43) Pub. Date: May 28, 2026

(54) CAPACITOR ON INTEGRATED CIRCUIT PACKAGE SUBSTRATE

(71) Applicant: Arm Limited, Cambridge (GB)

(72) Inventors: Yimajian Yan, Santa Clara, CA (US); Javier DeLaCruz, San Jose, CA (US); Cameron Cole Nelson, Gilbert, AZ (US); Sumant Srikant, Cambridge (GB)

(21) Appl. No.: 18/957,043

(22) Filed: Nov. 22, 2024

(51) Int. Cl. H01L 25/16; H01L 23/00; H01L 23/13

(52) U.S. Cl. CPC H10W 90/00; H10D 1/68; H10W 70/68; H10W 74/15; H10W 90/724; H10W 90/728; H10W 90/734; H10W 90/738

(57) ABSTRACT

An integrated circuit assembly comprises an integrated circuit die and a substrate electrically and physically coupled to the integrated circuit die. A capacitor is physically coupled to the substrate at a location physically between the integrated circuit die and the substrate, the capacitor electrically coupled to the integrated circuit die via at least one electrical connection.

### FIELD

The field relates to powering integrated circuit devices, and more specifically to a capacitor on an integrated circuit package substrate.

### BACKGROUND

Modern computerized devices process and store information in a variety of ways, including using processors that may have multiple cores and cache memory that may be associated with each of at least some of the processor cores. The processors in modern high-performance consumer electronics devices such as smart phones, tablet computers, set top boxes, and the like, may have different processor cores with different capabilities, such as high-performance processor cores that can perform a high number of operations per second but that may consume a significant amount of power, and efficient cores that may perform tasks more efficiently but at a lower peak number of instructions per second than high performance cores. In some further examples, at least some of the high-performance cores and/or efficient cores may have configurable performance levels, such as underdriven or overdriven voltage levels and corresponding faster or reduced operating speeds.

Processor cores in some examples may be powered up or down as needed, and in further examples may have one or more different available performance levels (and associated efficiency levels) per core. For example, a demanding video game involving rendering many objects in real time may use both high-performance cores and all the high-efficiency cores in a smartphone, while a simple task like reading email may use a single high-efficiency core. Cores may therefore be selectively powered up or selectively employed to process program instructions depending on the task load in a computing device, typically involving significant changes in power demand as different processor cores are made active or employed to process instructions.

A large integrated circuit die may also have variances in semiconductor behavior across the die or between dies (sometimes known as process corner variances), and voltages needed for different clock frequencies or performance levels of different cores may also vary significantly. Individual control of voltages for each processor core or group of processor cores is therefore desirable in some multi-core computing systems to minimize power consumption by providing each core with no more than the voltage required for reliable operation at a given performance level or clock frequency. High granularity of voltage level provided to different processor cores in a computing system via voltage regulation external to the integrated circuit die may simplify power delivery to the die, but may present challenges related to the physical wire distance and impedance between the voltage regulator and the integrated circuit die.

Multi-core processors in modern computing systems may also have their own cache memory, such as a dedicated level one (L1) or level two (L2) cache memory associated with some or all of the respective processor cores in the multi-core processor. L1 or L2 cache local to one or more processor cores may store frequently-used data local to the respective cores, which may make retrieval of this often-used data faster than if the same data was retrieved from Level 3 (L3) cache or main memory (or DRAM) that is typically slower and physically more remote. Cache memory may typically contain tens of thousands or hundreds of thousands (or more) of words of data per core, comprising a significant percentage of the die area, transistor count, and power consumed by the integrated device, and may be powered up and down or switched between active and inactive power states as processor cores are powered up and down.

When processor cores are powered on to provide greater computing resources for a computing system, they may quickly draw significantly more current than before the cores and cache were powered, potentially causing a droop in voltage provided to the processor circuits. High-performance application such as servers configured to process artificial intelligence workloads may further contain thousands of cores, including hundreds of cores per integrated circuit, drawing power exceeding a kilowatt. Providing power to such cores through a voltage regulator on a motherboard may present some difficulty due to the physical distance and impedance between the voltage regulator circuitry and the integrated circuit die. Voltage regulators are often therefore designed to provide high current capability to an integrated circuit die while limiting effects such as voltage droop. But, voltage regulator circuitry may be slow to respond due to factors such as physical distance and impedance between the voltage regulator and integrated circuit. For reasons such as these, a need exists for improved voltage supply and regulation in powering integrated circuits such as processor cores and associated cache memory.

### BRIEF DESCRIPTION OF THE DRAWINGS

The claims provided in this application are not limited by the examples provided in the specification or drawings, but their organization and/or method of operation, together with features, and/or advantages may be best understood by reference to the examples provided in the following detailed description and in the drawings, in which:

FIG. 1 is a side view of an integrated circuit package comprising a substrate and a capacitor, consistent with an example embodiment.

FIG. 2 is a side view of an integrated circuit package comprising a capacitor mounted in a cavity within a substrate, consistent with an example embodiment.

FIG. 3 is a side view of an integrated circuit package comprising a capacitor mounted within a cavity on a substrate having direct electrical connections to an integrated circuit die, consistent with an example embodiment.

FIG. 4 is a side view of an integrated circuit package comprising a capacitor mounted on a substrate and an external package, consistent with an example embodiment.

FIG. 5 is a side view of an integrated circuit package comprising a capacitor mounted within a cavity on a substrate and an interposer, consistent with an example embodiment.

FIG. 6 is a flow diagram of a method of forming an integrated circuit assembly with a capacitor mounted between an integrated circuit die and a substrate, consistent with an example embodiment.

FIG. 7 shows a block diagram of a general-purpose computerized system, consistent with an example embodiment.

Reference is made in the following detailed description to accompanying drawings, which form a part hereof, wherein like numerals may designate like parts throughout that are corresponding and/or analogous. The figures have not necessarily been drawn to scale, such as for simplicity and/or clarity of illustration. For example, dimensions of some aspects may be exaggerated relative to others. Other embodiments may be utilized, and structural and/or other changes may be made without departing from what is claimed. Directions and/or references, for example, such as up, down, top, bottom, and so on, may be used to facilitate discussion of drawings and are not intended to restrict application of claimed subject matter. The following detailed description therefore does not limit the claimed subject matter and/or equivalents.

### DETAILED DESCRIPTION

In the following detailed description of example embodiments, reference is made to specific example embodiments by way of drawings and illustrations. These examples are described in sufficient detail to enable those skilled in the art to practice what is described, and serve to illustrate how elements of these examples may be applied to various purposes or embodiments. Other embodiments exist, and logical, mechanical, electrical, and other changes may be made.

Features or limitations of various embodiments described herein, however important to the example embodiments in which they are incorporated, do not limit other embodiments, and any reference to the elements, operation, and application of the examples serve only to aid in understanding these example embodiments. Features or elements shown in various examples described herein can be combined in ways other than shown in the examples, and any such combinations is explicitly contemplated to be within the scope of the examples presented here. The following detailed description does not, therefore, limit the scope of what is claimed.

Many modern computing systems employ processors with multiple processing cores, such that certain tasks that can be performed in parallel can be distributed among the cores for faster execution or different tasks can be performed simultaneously by different processors. Simple tasks such as checking an email may only use one processor core, while more complex tasks such as rendering a video game in real time may use all available cores. The processor cores in further examples may be associated with cache memory local to one or more of the respective processor cores, operable to store information that the processor core is likely to need for executing program instructions using local SRAM for fast access.

In some examples the different processor cores may also include different types of circuits, such as high performance processor cores, high efficiency processor cores, memory, and other such circuits. These circuits may vary in power demand, in physical location on the die, and on power demand per unit of area on the die. Powering processor cores and their related caches up and down changes the current drawn from the power source for the processor cores (and, in some further examples, associated cache memory), and may cause a temporary droop in supplied voltage while the voltage regulator or other power supply components recover from the increased demand for power. This voltage droop may be controlled to some degree using methods such as a low-dropout voltage regulator that responds somewhat quickly to changes in drawn current, by using bypass capacitors to store extra charge that is available to help meet a sudden demand for additional current, or through other such means. But, the impedance of solutions such as low-dropout voltage regulators or capacitors and the distance between the integrated circuit die and such power components may limit their ability to respond quickly to changes in power demand. Problems such as these may be exacerbated by high-performance or high-density integrated circuit devices, such as integrated circuits holding hundreds of processor cores for machine learning processing that may consume hundreds or thousands of watts of power.

Some examples presented herein therefore provide for an improved capacitor assembly for integrated circuit dies and packages, comprising a capacitor that may be physically located between an integrated circuit die and a package substrate. In one such example, an integrated circuit die is electrically and physically coupled to a substrate, and a capacitor is physically coupled to the substrate at a physical location between the integrated circuit die and the substrate. In a further example, the capacitor may be located at least partially within a cavity in the substrate, such as to accommodate a physically larger capacitor having a higher capacitance. In another example, two or more integrated circuit dies may be mounted to an interposer that is in turn mounted to a substrate, and capacitors may be mounted between the integrated circuit dies and the interposer and/or between the interposer and the substrate.

In another example, a method of forming an integrated circuit assembly comprises physically and electrically coupling a capacitor to a substrate, and physically and electrically coupling the substrate to an integrated circuit die such that the capacitor is physically located between the substrate and the integrated circuit die and is electrically coupled to the integrated circuit die. In a further example, the method further comprises forming a cavity in the substrate and physically and electrically coupling the capacitor to the substrate in the cavity formed in the substrate. In another example, the method further comprises underfilling at least one of a gap between the capacitor and the substrate and a gap between the substrate and the integrated circuit die.

Other examples comprise an integrated circuit assembly, comprising an integrated circuit die, and a substrate electrically and physically coupled to the integrated circuit die. A power supply component is electrically and physically coupled to the substrate at a location physically between the integrated circuit die and the substrate, the substrate electrically coupling the power supply component to the integrated circuit die. In a further example, the power supply component comprises a capacitor, an inductor, a voltage regulator, or another power supply component.

Examples such as these illustrate how a power supply component such as a capacitor can be mounted physically near an integrated circuit die by placing the component between the integrated circuit die and a substrate, shortening the length and reducing the impedance of electrical connections between the integrated circuit die and the capacitor or other power supply component. Such an assembly may allow the capacitor to more quickly respond to changes in supplied voltage on the integrated circuit die, such as during transients or rapid changes in drawn current, and may provide for more efficient delivery of power to the integrated circuit die with less loss, delay, and other impedance-related or distance-related artifacts.

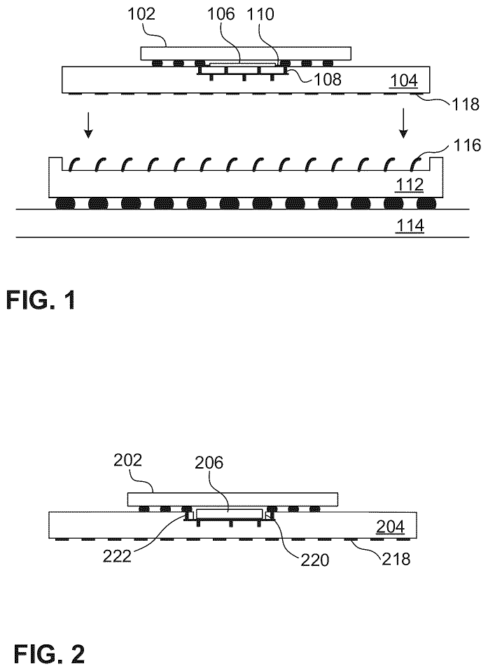

FIG. 1 is a side view of an integrated circuit package comprising a substrate and a capacitor, consistent with an example embodiment. Here, an integrated circuit die 102 is electrically and physically coupled to a substrate 104. The integrated circuit may in various embodiments comprise various digital analog, or mixed circuits. Digital circuit examples include one or more processor cores, graphics processors, memory, signal processors, and other digital circuits, while analog circuit examples include amplifiers, filters, analog communication circuits, and the like. Mixed signal integrated circuits may contain both digital and analog circuits on the same device, such as a wireless networking integrated circuit operable to process both analog radio waves and digital data signals to facilitate transmission and/or reception of digital data using analog radio waves. The substrate 104 in various examples may comprise a fiberglass and resin, organic laminate, ceramic, or other suitable material, and may contain within one or more conductive layers comprising various signal, power, and other electrical interconnects coupling the flip-chip bumps to ball grid array (BGA) solder balls, Land Grid Array (LGA) contact pads, Pin Grid Array pins, or other package electrical connections.

The substrate 104 in this example is further connected to a capacitor 106, which is electrically coupled to the integrated circuit die via one or more electrical connections such as vias 108 and/or conductive traces 110. The capacitor may typically have both a positive or anode connection and a negative or cathode connection to external circuitry, such as the integrated circuit die, which may take various forms such as direct electrical connections or a direct positive connection and a shared common or ground signal. The capacitor in some embodiments may be coupled to a power supply signal powering the integrated circuit die, such as a power supply signal for one or more high performance processor cores, to store energy to be released during voltage transients such as voltage droop experienced when increasing the current drawn from the power supply signal. In further examples, the capacitor may be augmented by one or more additional power supply components, such as a voltage regulator, a DC to DC voltage converter, and one or more inductors. These power supply components may be physically large relative to other electronic components on or near the integrated circuit die 102, and so are external to the integrated circuit die but may desirably be physically near the integrated circuit die to reduce impedance and physical electronic connection distance between the capacitor 106 and the integrated circuit die 102 to improve responsiveness to voltage transients. By mounting the capacitor between the integrated circuit die 102 and the substrate 104, electrical connections between the capacitor and the integrated circuit die's circuitry are relatively short and low impedance, providing fast and efficient response to voltage droops or other power transients.

The assembly shown at 102-110 comprises in the example of FIG. 1 a die, a substrate, and a capacitor that may be coupled to a printed circuit board or otherwise coupled to a circuit such as a computerized system via a socket 112. The assembly shown at 102-110 may in other embodiments comprise additional components, such as underfill material filling gaps between solder balls in the flip chip ball grid array coupling the integrated circuit die 102 to the substrate 104, preventing thermal stress from heating and cooling air pockets between the socket and the printed circuit board and protecting the capacitor 106 mounted between the integrated circuit die and the substrate. In further examples, a protective package covering the top of the die 102 and providing thermal conductivity to a heat sink for the integrated circuit die, an array of external electrical contacts, and/or other such components may be employed. The example of FIG. 1 further shows a socket 112 coupled to a printed circuit board 114, and includes an array of semi-flexible pins 116 forming part of a Land Grid Array (LGA) chip/socket interface, where the pins 116 are operable to make physical and electrical contact with a corresponding array of conductive pads 118 on the substrate 104.

The socket 112 in this example is coupled to the printed circuit board 114 via solder balls that are larger than the flip chip ball grid array solder balls coupling the integrated circuit die 102 to the substrate 104. These solder balls may be a ball grid array, and may be underfilled such as with an epoxy resin or other material that flows via capillary action to fill air space between the socket 112 and the printed circuit board 114 to prevent thermal stress from heating and cooling air pockets between the socket and the printed circuit board. The socket 112 in other examples may be another type of socket, such as a pin socket, a Pin Grid Array (PGA) socket, or another suitable socket designed or configured to physically and electrically connect to the substrate 104. Circuit traces on the printed circuit board 114 are thereby electrically connected to the integrated circuit die 102 via the socket and the substrate, and the various physical and electrical connection mechanisms that may be employed to couple these components to one another.

The die 102, substrate 104, and capacitor 106 are configured in the example of FIG. 1 such that the capacitor is physically near the integrated circuit die, and electrical connections between the substrate 104 and capacitor 106 are relatively short and have a relatively low impedance. This enables relatively rapid response to changes in power supply signal voltage in the integrated circuit die 102, and relatively low losses due to impedance or physical distance between the capacitor and the integrated circuit die. The configuration of FIG. 1 may therefore be able to respond to changes in power demand and associated voltage transients better than other known configurations, and may experience less loss or delay in providing energy from the capacitor to resist voltage droop during changes in power demand due to the physical proximity and reduced impedance between the capacitor and the integrated circuit die.

FIG. 2 is a side view of an integrated circuit package comprising a capacitor mounted in a cavity within a substrate, consistent with an example embodiment. Here, an integrated circuit die 202 is attached to a substrate 204 such as using a flip chip ball grid array and underfill, similar to the example of FIG. 1. A capacitor 206 is similarly mounted to the substrate 204, but is located at least partially within a cavity 220 formed in an integrated circuit die mounting surface of the substrate 204. In a more detailed example, the substrate 204 has a cavity 220 formed therein before assembly of the substrate 204, integrated circuit die 202, and capacitor 206, such that the cavity is configured to at least partially receive the capacitor. In further examples, the cavity 220 is configured to provide one or more electrical connections such as a pair of vias 222 that are electrically coupled to the capacitor, to include a thermal sink for heat conducted from the capacitor, or to include an underfill material configured to encapsulate the capacitor 206 and fill any voids within the cavity 220 and/or between the integrated circuit die 202 and the substrate 204.

The cavity 220 may be formed in the substrate using laser or other energy etching, grinding or other mechanical ablation, chemical removal, lamination of substrate layers having different profiles, or other suitable methods in various embodiments. The cavity in some examples may be larger than the physical dimensions of the capacitor, such as at least 10 microns wider in each dimension than the capacitor, to allow the capacitor to be easily received in the cavity without unnecessarily strict tolerance requirements or pressure fitting the capacitor to the cavity. The integrated circuit assembly comprising the integrated circuit die 202, substrate 204, and capacitor 206 are again configured in the example of FIG. 2 to be coupled to a printed circuit board such as in the example of FIG. 1, receiving power supply signals, sending and receiving data, and performing other such functions via electrical pads 218.

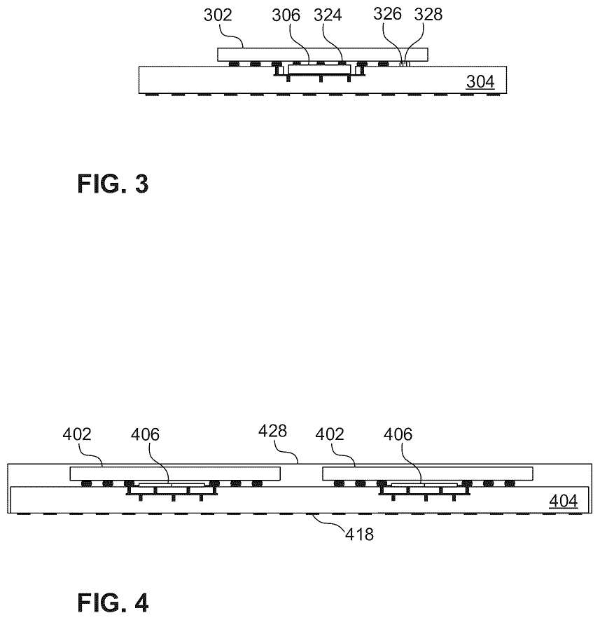

FIG. 3 is a side view of an integrated circuit package comprising a capacitor mounted within a cavity on a substrate having direct electrical connections to an integrated circuit die, consistent with an example embodiment. Here, the integrated circuit die 302 is coupled to the substrate 304, and a capacitor 206 is at least partially positioned within a cavity in the substrate to facilitate accommodating a physically large capacitor between the substrate 304 and the integrated circuit die 302. The capacitor 306 in this example comprises one or more electrical connections directly between the capacitor and the die, such as through solder bumps 324. The solder bumps 324 may be smaller and/or finer in pitch than solder bumps or ball grid array bumps 326 that connect the integrated circuit die 302 to the substrate 304, such as to accommodate a narrower gap between the capacitor and the integrated circuit die than between the substrate and the integrated circuit die.

Directly connecting the capacitor 306 to the integrated circuit die may further reduce the electrical impedance between the circuitry on the integrated circuit die and the capacitor, enabling the capacitor to release more energy more quickly to the integrated circuit's circuitry during transitions in performance of processor cores or during other periods of voltage droop. Impedance in this example may include resistance, which may cause dissipation of energy before it reaches the core and may contribute to an RC time constant that limits the discharge rate of the capacitor 306, and may include inductance, which resists a change in the amount of current flowing from the capacitor to the integrated circuit's circuitry. Reducing these impedance components by connecting the capacitor directly to the integrated circuit die may therefore improve the capacitor's ability to rapidly and efficiently provide electrical charge to reduce voltage droop during transients in drawn power, such as when starting or increasing the operating level of high performance processor cores or other such circuitry.

FIG. 4 is a side view of an integrated circuit package comprising a capacitor mounted on a substrate and an external package, consistent with an example embodiment. Here, the integrated circuit die 402, substrate 404, and capacitor 406 are configured much as the previous examples, but further include a package 428. The package material in various examples may comprise a metal shell or lid, a ceramic material, a plastic or polymer material, or a combination of such materials and/or other materials. The package in this example is configured such that electrical contacts such as Land-Grid Array (LGA) pads 418 are exposed external to the package to provide electrical connectivity to a socket, while other examples may include pins, Ball-Grid Array (BGA) solder bumps, or other electrical connections. The integrated circuit package in a further example comprises a thermally conductive material coupling the die 402 to the package 428, such as a thermal paste or the like. This may facilitate dissipation of heat generated in the integrated circuit die 402 to the package 428, such as a metal case, and in further examples facilitate heat transfer from the die to the metal case and further to a heat sink thermally coupled to the metal case. Some or all of the void space between the die 402 and the substrate 404 may be filled with an underfill, encapsulant, or overmold material in various embodiments. Some such embodiments may employ a film or paste, while other examples may employ a liquid material that fills the space such as via capillary action and/or application under pressure. The fill material may be epoxy in some embodiments, or may be another resin, polymer, or other suitable material in further examples. These fill materials in some embodiments may be further used to fill space within the package 428, providing a mechanical, thermal, and/or other coupling between the package 428 and the internal components such as substrate 404 and integrated circuit die 402.

In some examples, more than one capacitor may be present per integrated circuit die, such as to support different power supply signals at different voltage levels for different processor cores on a die, or due to different discharge characteristics of different capacitor technologies. In one such example, Multi-Layer Ceramic Capacitors (MLCC capacitors) having a relatively high discharge impedance but high capacitance for their volume may be supplemented by deep trench capacitors that have lower capacitance per volume but have lower discharge impedance and may provide a stored charge to mitigate voltage droop more quickly than MLCC capacitors. In other examples, other types of capacitors may be employed, such as thin film or metallized film capacitors, tantalum or other electrolytic capacitors, and other types of capacitors. Some examples may further use multiple dies per substrate, multiple capacitors per substrate or per die, or use interposers between the substrate and integrated circuit dies to package multiple components on a substrate.

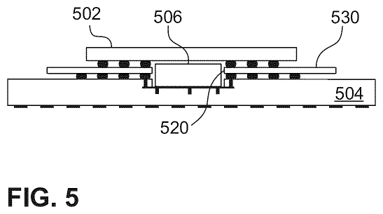

FIG. 5 is a side view of an integrated circuit package comprising a capacitor mounted within a cavity on a substrate and an interposer, consistent with an example embodiment. Here, an integrated circuit die 502, substrate 504, and a capacitor 506 are configured much as in the example of FIG. 2, but an interposer 530 is configured between the integrated circuit die 502 and the substrate 504. The interposer in some examples may include a cavity to accommodate at least a portion of the capacitor 506 in the interposer such that the capacitor is physically located between the integrated circuit die 502 and the interposer 530. In other examples such as that shown in FIG. 5, the interposer may comprise an opening or hole 520 configured to accommodate the capacitor 506, such that the capacitor is physically located between the substrate 504 and the integrated circuit die while passing through the hole 520 formed in the interposer. In various further examples, the substrate 504 may or may not have an additional cavity formed therein to receive at least an additional portion of the capacitor therein, allowing a significantly larger capacitor than may fit between an integrated circuit and a substrate with no such interposer or substrate cavity (such as is shown in the example of FIG. 1).

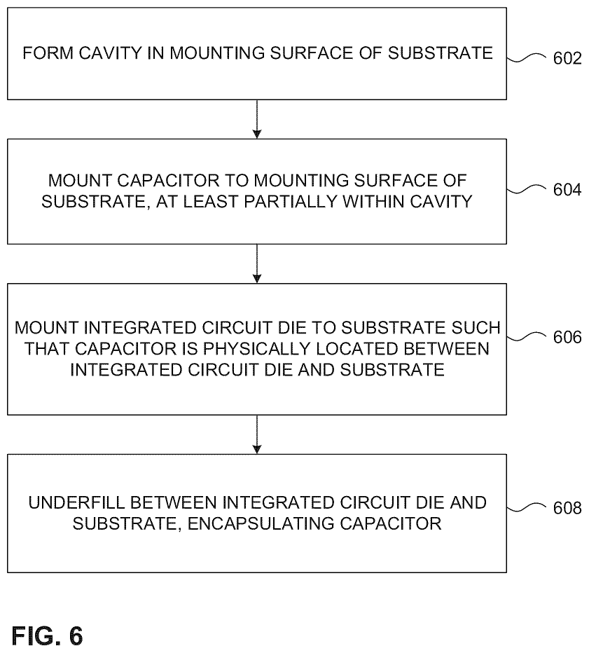

FIG. 6 is a flow diagram of a method of forming an integrated circuit assembly with a capacitor mounted between an integrated circuit die and a substrate, consistent with an example embodiment. In the example of FIG. 6, a cavity is first formed in the substrate at 602, which in a further example may have dimensions sufficient to accommodate a capacitor of known size at least partially within the cavity and between the substrate and an integrated circuit die, such as by having a clearance of 10 microns or greater on each side of the cavity between the substrate and the capacitor. The capacitor is mounted to the mounting surface of the capacitor at 604, and is at least partially physically located within the cavity formed in the substrate. In an alternate example, no cavity is formed in the substrate at 602, and the capacitor is mounted to a mounting surface of the substrate.

At 606, the integrated circuit die is mounted to the substrate, such as by flowing an array of solder balls (sometimes known as a Ball Grid Array or BGA) coupling electrical contacts or pads on the substrate to corresponding electrical contacts or pads on the substrate. Once the integrated circuit die is coupled to the substrate, the capacitor is physically located between the substrate and the integrated circuit die. Gaps between the integrated circuit die and the substrate may be underfilled at 608, such as using a paste, a film, a capillary flow or pressurized liquid, or another suitable material. The material in various examples may be epoxy, or another suitable resin, or a curable polymer, such that the material may effectively eliminate or substantially reduce air gaps between the integrated circuit die, the capacitor, and the substrate.

In a further example, an interposer may be situated between the integrated circuit die and the substrate, such as to accommodate more than one integrated circuit die or additional components that are to be coupled to the substrate. In one such example, an interposer is formed between steps 604 and 606, such that the interposer has a hole formed therein corresponding to the capacitor's position on the substrate (such as corresponding to a cavity formed in the surface of the substrate to accommodate the capacitor in some embodiments). The interposer is then mounted to the substrate and the integrated circuit die is mounted to the interposer, such that the interposer is “sandwiched” between the substrate and the integrated circuit die. The capacitor in such an example may remain physically located between the integrated circuit die and the substrate, but may further reside at least partially within a hole or opening within the interposer.

The examples presented herein illustrate how a capacitor may be positioned physically between an integrated circuit die and a substrate such that signal travel distance and signal impedance between the capacitor and the integrated circuit die are low. A cavity may be used in a substrate to receive at least part of the capacitor in some embodiments, which in some examples is desirable to create sufficient space between the substrate and the integrated circuit die for the capacitor to reside. In some further examples, one or more direct connections between the capacitor and the integrated circuit die may be formed, such as using solder bumps or other suitable connection means. Various examples may also incorporate an interposer physically located between the integrated circuit die and the substrate, such as to accommodate additional integrated circuit dies or other electrical components, and a hole or opening in the substrate may be formed to accommodate the capacitor that is similarly physically disposed between the integrated circuit die and the substrate.

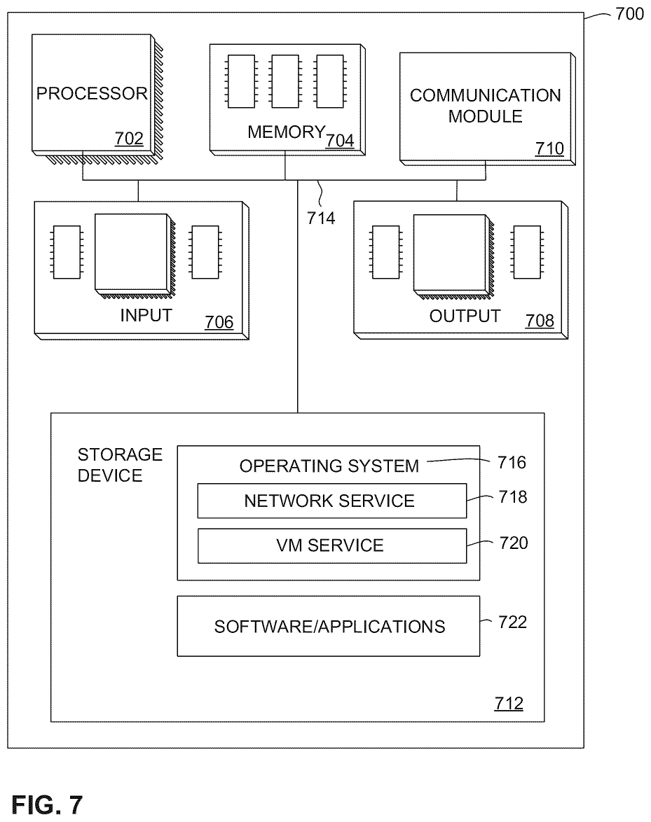

FIG. 7 shows a block diagram of a general-purpose computerized system, consistent with an example embodiment. FIG. 7 illustrates only one particular example of computing device 700, and other computing devices 700 may be used in other embodiments. Although computing device 700 is shown as a standalone computing device, computing device 700 may be any component or system that includes one or more processors or another suitable computing environment for executing software instructions in other examples, and need not include all of the elements shown here.

As shown in the specific example of FIG. 7, computing device 700 includes one or more processors 702, memory 704, one or more input devices 706, one or more output devices 708, one or more communication modules 710, and one or more storage devices 712. Computing device 700, in one example, further includes an operating system 716 executable by computing device 700. The operating system includes in various examples services such as a network service 718 and a virtual machine service 720 such as a virtual server. One or more applications, such as application 722 are also stored on storage device 712, and are executable by computing device 700.

Each of components 702, 704, 706, 708, 710, and 712 may be interconnected (physically, communicatively, and/or operatively) for inter-component communications, such as via one or more communications channels 714. In some examples, communication channels 714 include a system bus, network connection, inter-processor communication network, or any other channel for communicating data. Applications such as software application 722 and operating system 916 may also communicate information with one another as well as with other components in computing device 700.

Processors 702, in one example, are configured to implement functionality and/or process instructions for execution within computing device 700. For example, processors 702 may be capable of processing instructions stored in storage device 712 or memory 704. Examples of processors 702 include any one or more of a microprocessor, a controller, a central processing unit (CPU), a graphics processing unit (GPU), a neural processing unit (NPU), an image signal processor (ISP), a digital signal processor (DSP), an application specific integrated circuit (ASIC), a field-programmable gate array (FPGA), or similar discrete or integrated logic circuitry.

One or more storage devices 712 may be configured to store information within computing device 700 during operation. Storage device 712, in some examples, is known as a computer-readable storage medium. In some examples, storage device 712 comprises temporary memory, meaning that a primary purpose of storage device 712 is not long-term storage. Storage device 712 in some examples is a volatile memory, meaning that storage device 712 does not maintain stored contents when computing device 700 is turned off. In other examples, data is loaded from storage device 712 into memory 704 during operation. Examples of volatile memories include random access memories (RAM), dynamic random access memories (DRAM), static random access memories (SRAM), and other forms of volatile memories known in the art. In some examples, storage device 712 is used to store program instructions for execution by processors 702. Storage device 712 and memory 704, in various examples, are used by software or applications running on computing device 700 such as software application 722 to temporarily store information during program execution.

Storage device 712, in some examples, includes one or more computer-readable storage media that may be configured to store larger amounts of information than volatile memory. Storage device 712 may further be configured for long-term storage of information. In some examples, storage devices 712 include non-volatile storage elements. Examples of such non-volatile storage elements include magnetic hard discs, optical discs, floppy discs, flash memories, or forms of electrically programmable memories (EPROM) or electrically erasable and programmable (EEPROM) memories.

Computing device 700, in some examples, also includes one or more communication modules 710. Computing device 700 in one example uses communication module 710 to communicate with external devices via one or more networks, such as one or more wireless networks. Communication module 710 may be a network interface card, such as an Ethernet card, an optical transceiver, a radio frequency transceiver, or any other type of device that can send and/or receive information. Other examples of such network interfaces include Bluetooth, 4G, LTE, or 5G, WiFi radios, and Near-Field Communications (NFC), and Universal Serial Bus (USB). In some examples, computing device 700 uses communication module 710 to wirelessly communicate with an external device such as via a public network.

Computing device 700 also includes in one example one or more input devices 706. Input device 706, in some examples, is configured to receive input from a user through tactile, audio, or video input. Examples of input device 706 include a touchscreen display, a mouse, a keyboard, a voice responsive system, video camera, microphone or any other type of device for detecting input from a user.

One or more output devices 708 may also be included in computing device 700. Output device 708, in some examples, is configured to provide output to a user using tactile, audio, or video stimuli. Output device 708, in one example, includes a display, a sound card, a video graphics adapter card, or any other type of device for converting a signal into an appropriate form understandable to humans or machines. Additional examples of output device 808 include a speaker, a light-emitting diode (LED) display, a liquid crystal display (LCD or OLED), or any other type of device that can generate output to a user.

Computing device 700 may include operating system 716. Operating system 716, in some examples, controls the operation of components of computing device 700, and provides an interface from various applications such as software application 722 to components of computing device 700. For example, operating system 716, in one example, facilitates the communication of various applications such as software application 722 with processors 702, communication unit 710, storage device 712, input device 706, and output device 708. Applications such as application 722 may include program instructions and/or data that are executable by computing device 700. These and other program instructions or modules may include instructions that cause computing device 700 to perform one or more of the other operations and actions described in the examples presented herein.

Process cores, bitcell arrays, memory structures, peripheral circuitry, and other circuits as described herein in particular examples may be formed in whole or in part by and/or expressed in transistors and/or lower metal interconnects (not shown) in processes (e.g., front end-of-line and/or back-end-of-line processes) such as processes to form complementary metal oxide semiconductor (CMOS) circuitry. The various blocks, neural networks, and other elements disclosed herein may be described using computer aided design tools and expressed (or represented), as data and/or instructions embodied in various computer-readable media, in terms of their behavioral, register transfer, logic component, transistor, layout geometries, and/or other characteristics.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Features of example computing devices employed in example embodiments may comprise features, for example, of a client computing device and/or a server computing device. The term computing device, in general, whether employed as a client and/or as a server, or otherwise, refers at least to a processor and a memory connected by a communication bus. A “processor” and/or “processing circuit” for example, is understood to connote a specific structure such as a central processing unit (CPU), digital signal processor (DSP), graphics processing unit (GPU), image signal processor (ISP) and/or neural processing unit (NPU), or a combination thereof, of a computing device which may include a control unit and an execution unit. In an aspect, a processor and/or processing circuit may comprise a device that fetches, interprets and executes instructions to process input signals to provide output signals. As such, in the context of the present patent application at least, this is understood to refer to sufficient structure within the meaning of 35 USC § 112 (f) so that it is specifically intended that 35 USC § 112 (f) not be implicated by use of the term “computing device,” “processor,” “processing unit,” “processing circuit” and/or similar terms; however, if it is determined, for some reason not immediately apparent, that the foregoing understanding cannot stand and that 35 USC § 112 (f), therefore, necessarily is implicated by the use of the term “computing device” and/or similar terms, then, it is intended, pursuant to that statutory section, that corresponding structure, material and/or acts for performing one or more functions be understood and be interpreted to be described at least in FIG. 1 and in the text associated with the foregoing figure(s) of the present patent application.

Some embodiments may be described, at least in part, by the following numbered clauses or by any combination thereof:

Clause 1: An assembly, comprising: an integrated circuit die; a substrate electrically and physically coupled to the integrated circuit die, and a capacitor physically coupled to the substrate at a location physically between the integrated circuit die and the substrate, the capacitor electrically coupled to the integrated circuit die via at least one electrical connection.

Clause 2: The assembly of clause 1, further comprising a cavity formed in the substrate, the capacitor positioned at least partially within the cavity.

Clause 3: The assembly of clause 2, wherein the capacitor positioned at least partially within the cavity has a thickness greater than a gap between the integrated circuit die and the substrate.

Clause 4: The assembly of any of the aforementioned clauses, wherein the capacitor is electrically coupled to the integrated circuit die via at least one electrical connection between the capacitor and the substrate and at least one electrical connection between the substrate and the integrated circuit die.

Clause 5: The assembly of any of the aforementioned clauses, wherein the capacitor is electrically coupled to the integrated circuit die via at least one die to die interconnect.

Clause 6: The assembly of any of the aforementioned clauses, further comprising an underfill material filling a space between the integrated circuit die and the substrate physically coupled to the capacitor.

Clause 7: The assembly of clause 6, further comprising an underfill material filling a space between the capacitor and the substrate.

Clause 8: The assembly of any of the aforementioned clauses, further comprising at least one additional integrated circuit die electrically and physically coupled to the substrate, and at least one additional capacitor physically coupled to the substrate at a location physically between one or more of the at least one additional integrated circuit dies and the substrate, the at least one additional capacitor electrically coupled to the respective at least one additional integrated circuit dies via at least one electrical connection.

Clause 9: The assembly of any of the aforementioned clauses, further comprising an interposer physically located between the integrated circuit die and the substrate, the capacitor further physically located between the interposer and the substrate.

Clause 10: The assembly of clause 9, the interposer having an opening formed therein, the capacitor at least partially located within the opening in the interposer.

Clause 11: The assembly of any of the aforementioned clauses, wherein the substrate comprises an interposer and the interposer is electrically and physically connected to a second substrate.

Clause 12: The assembly of any of the aforementioned clauses, wherein the capacitor comprises one or more of a multi-layer chip capacitor (MLCC), a deep trench capacitor, or a thin film capacitor.

Clause 13: The assembly of clause 12, wherein the capacitor comprises more than one capacitor type.

Clause 14: The assembly of any of the aforementioned clauses, further comprising one or more copper pillars soldered between the integrated circuit die and the substrate.

Clause 15: The assembly of any of the aforementioned clauses, further comprising at least one additional electronic component physically coupled to the substrate at the location physically between the integrated circuit die and the substrate, the at least one additional electronic component electrically coupled to the integrated circuit die via at least one electrical connection.

Clause 16: The assembly of clause 15, wherein the at least one additional electronic component comprises at least one of an inductor or a semiconductor.

Clause 17: A method of forming an assembly, comprising:
physically and electrically coupling a capacitor to a substrate;
physically and electrically coupling the substrate to an integrated circuit die such that the capacitor is physically located between the substrate and the integrated circuit die and is electrically coupled to the integrated circuit die.

Clause 18: The method of forming an assembly of clause 17, further comprising forming a cavity in the substrate and physically and electrically coupling the capacitor to the substrate in the cavity formed in the substrate.

Clause 19: The method of forming an assembly of any of clauses 17-18, further comprising underfilling at least one of a gap between the capacitor and the substrate and a gap between the substrate and the integrated circuit die.

Clause 20: An assembly, comprising: an integrated circuit die; a substrate electrically and physically coupled to the integrated circuit die, and a power supply component electrically and physically coupled to the substrate at a location physically between the integrated circuit die and the substrate, the substrate electrically coupling the power supply component to the integrated circuit die.

Although specific embodiments have been illustrated and described herein, any arrangement that achieve the same purpose, structure, or function may be substituted for the specific embodiments shown. This application is intended to cover any adaptations or variations of the example embodiments of the invention described herein. These and other embodiments are within the scope of the following claims and their equivalents.

What is claimed is:

1. An assembly, comprising:
an integrated circuit die;
a substrate electrically and physically coupled to the integrated circuit die, and
a capacitor physically coupled to the substrate at a location physically between the integrated circuit die and the substrate, the capacitor electrically coupled to the integrated circuit die via at least one electrical connection.

2. The assembly of claim 1, further comprising a cavity formed in the substrate, the capacitor positioned at least partially within the cavity.

3. The assembly of claim 2, wherein the capacitor positioned at least partially within the cavity has a thickness greater than a gap between the integrated circuit die and the substrate.

4. The assembly of claim 1, wherein the capacitor is electrically coupled to the integrated circuit die via at least one electrical connection between the capacitor and the substrate and at least one electrical connection between the substrate and the integrated circuit die.

5. The assembly of claim 1, wherein the capacitor is electrically coupled to the integrated circuit die via at least one die to die interconnect.

6. The assembly of claim 1, further comprising an underfill material filling a space between the integrated circuit die and the substrate physically coupled to the capacitor.

7. The assembly of claim 6, further comprising an underfill material filling a space between the capacitor and the substrate.

8. The assembly of claim 1, further comprising at least one additional integrated circuit die electrically and physically coupled to the substrate, and at least one additional capacitor physically coupled to the substrate at a location physically between one or more of the at least one additional integrated circuit dies and the substrate, the at least one additional capacitor electrically coupled to the respective at least one additional integrated circuit dies via at least one electrical connection.

9. The assembly of claim 1, further comprising an interposer physically located between the integrated circuit die and the substrate, the capacitor further physically located between the interposer and the substrate.

10. The assembly of claim 9, the interposer having an opening formed therein, the capacitor at least partially located within the opening in the interposer.

11. The assembly of claim 1, wherein the substrate comprises an interposer and the interposer is electrically and physically connected to a second substrate.

12. The assembly of claim 1, wherein the capacitor comprises one or more of a multi-layer chip capacitor (MLCC), a deep trench capacitor, or a thin film capacitor.

13. The assembly of claim 12, wherein the capacitor comprises more than one capacitor type.

14. The assembly of claim 1, further comprising one or more copper pillars soldered between the integrated circuit die and the substrate.

15. The assembly of claim 1, further comprising at least one additional electronic component physically coupled to the substrate at the location physically between the integrated circuit die and the substrate, the at least one additional electronic component electrically coupled to the integrated circuit die via at least one electrical connection.

16. The assembly of claim 15, wherein the at least one additional electronic component comprises at least one of an inductor or a semiconductor.

17. A method of forming an assembly, comprising:
physically and electrically coupling a capacitor to a substrate;
physically and electrically coupling the substrate to an integrated circuit die such that the capacitor is physically located between the substrate and the integrated circuit die and is electrically coupled to the integrated circuit die.

18. The method of forming an assembly of claim 17, further comprising forming a cavity in the substrate and physically and electrically coupling the capacitor to the substrate in the cavity formed in the substrate.

19. The method of forming an assembly of claim 17, further comprising underfilling at least one of a gap between the capacitor and the substrate and a gap between the substrate and the integrated circuit die.

20. An assembly, comprising:
an integrated circuit die;
a substrate electrically and physically coupled to the integrated circuit die, and
a power supply component electrically and physically coupled to the substrate at a location physically between the integrated circuit die and the substrate, the substrate electrically coupling the power supply component to the integrated circuit die.
